(19) United States
(12) Patent Application Publication
(10) Pub. No.: US 2024/0021428 A1
(43) Pub. Date: Jan. 18, 2024

(54) EPITAXIAL SUBSTRATE SURFACES FOR SEMICONDUCTOR MATERIAL GROWTH AND IMPROVED SMOOTH SEMICONDUCTOR SURFACES FOR HIGHER CHANNEL MOBILITY THROUGH THE FORMATION AND REMOVAL OF REACTIVE LAYERS

(71) Applicant: California Institute of Technology, Pasadena, CA (US)

(72) Inventors: Harold Frank Greer, Los Angeles, CA (US); Rehan Kapadia, Los Angeles, CA (US); Debargyha Sarkar, Pasadena, CA (US)

(73) Assignees: California Institute of Technology, Pasadena, CA (US); University of Southern California, Los Angeles, CA (US)

(21) Appl. No.: 18/352,175

(22) Filed: Jul. 13, 2023

Related U.S. Application Data
(60) Provisional application No. 63/388,756, filed on Jul. 13, 2022.

(51) Int. Cl. H01L 21/02; H01L 21/768; H01L 21/8238; H01L 23/532

(52) U.S. Cl. CPC H01L 21/0262; H01L 21/7684; H01L 21/823871; H01L 23/53238

(57) ABSTRACT

A method for processing a surface, comprising obtaining a substrate comprising an epitaxially grown semiconductor; reacting a surface of the semiconductor and/or a surface of a dielectric layer on the semiconductor, with a reactant comprising a gas or a plasma, to form a reactive layer on the dielectric layer and/or the semiconductor, wherein the reactive layer comprises a chemical compound including the reactant and elements of the dielectric layer or the semiconductor; and processing (e.g., removing, modifying, and/or chemically reducing) the reactive layer, wherein the processing at least smoothens, controls defects at, improves the electrical properties of, or the optical properties of, the surface

### CROSS REFERENCE TO RELATED APPLICATIONS

This application claims the benefit under 35 USC 119(e) of co-pending and commonly assigned U.S. Provisional Patent Application Ser. No. 63/388,756, filed Jul. 13, 2022, by Harold Frank Greer, Rehan Kapadia, Debargyha Sarkar, entitled “IMPROVED EPI SUBSTRATE SURFACES FOR III-V MATERIAL GROWTH USING ATOMIC LAYER ETCHING AND IMPROVED SMOOTH III-V SURFACES FOR HIGHER CHANNEL MOBILITY,” (CIT-8305-P), which application is incorporated by reference herein.

### STATEMENT REGARDING FEDERALLY SPONSORED RESEARCH AND DEVELOPMENT

This invention was made with government support under Grant No. 80NMO0018D0004 awarded by NASA (JPL). The government has certain rights in the invention.

### BACKGROUND OF THE INVENTION

### 1. Field of the Invention

The present invention relates to methods and systems for etching, surface engineering, and atomic layer deposition.

### 2. Description of the Related Art

Devices and elements in semiconductor, display, and optical systems are continuously shrinking in size and increasing in complexity. The simultaneous optimization of design, materials, fabrication processes, and in some cases, assembly of these devices into their final form is also particularly complicated. For either or both of these reasons, the smoothness and composition of the interfaces and surfaces of these components are particularly important because these properties can dominate the electrical and optical performance of these devices or elements. The magnitude of a change, including nanometer scale height differences in peak to valley for a semiconductor surface or atomic concentration differences of <1% for dopants or passivating atoms can make orders of magnitude difference in performance. Therefore, it is necessary to have atomic scale control of these interfaces. The present disclosure satisfies this need.

### SUMMARY OF THE INVENTION

Illustrative, non-exclusive examples of inventive subject matter according to the present disclosure are described in the following enumerated paragraphs.
1. A method for processing a surface, comprising:
(a) obtaining a substrate comprising an epitaxially grown semiconductor or an ordered substrate template for subsequent epitaxial growth of a semiconductor;
(b) reacting a surface of the semiconductor and/or a surface of a dielectric layer on the semiconductor, with a reactant comprising a gas, a plasma, or a fluid, to form a reactive layer on the dielectric layer and/or the semiconductor, wherein the reactive layer comprises a chemical compound including the reactant and elements of the dielectric layer or the semiconductor; and
(c) processing (e.g., removing, modifying, and/or chemically reducing) the reactive layer, wherein the processing at least smoothens, or controls defects at, the surface.
2. The method of example 1, wherein the processing comprises reacting the reactive layer with an agent that induces a re-arrangement of chemical bonds between constituents of the reactive layer and wherein the re-arrangement removes at least part of the constituents of the reactive layer from the surface.
3. The method of example 2, wherein the reacting comprises projecting the agent onto the surface with an energy:
below that required for physical sputtering of the surface using the agent so that the material is not ejected from the substrate by a physical sputtering process, and
sufficient to act as a catalyst for the re-arrangement.
4. The method of example 2, wherein the agent comprises ions.
5. The method of example 1, wherein the processing comprises accelerating ions onto the surface and selecting an angle of incidence of the ions with respect to a surface normal so as to smoothen or remove the defects from the surface.
6. The method of example 1, wherein the processing comprises accelerating ions onto the surface and at least one of:
selecting a temperature of the processing,
selecting an angle of incidence of the processing,
selecting a composition of the reactant, or
selecting an angle of incidence of the ions onto the surface, and
so as to control anisotropy or isotropy of removal of the reactive layer.
7. The method of example 6, wherein the processing comprises removing the reactive layer along a direction having a larger component parallel to the surface of the reactive layer, as compared to the component normal to the surface.
8. The method of example 1, wherein the formation of the reactive layer comprises and at least one of:
selecting a temperature of the processing, or
selecting a composition of the reactant,
so as to control anisotropy or isotropy of formation of the reactive layer.
9. The method of example 1, wherein the processing comprises chemical sputtering.
10. The method of example 1, wherein the processing comprises wet etching with a liquid wet etchant.
10. The method of example 1, wherein the reactive layer comprises valleys having sidewalls and the processing etches the valleys laterally through the sidewalls so as to planarize the surface and remove or connect the valleys.
11. The method of example 9, wherein the valleys have a height and width in a range of 1-1000 nm.
12. The method of example 1, wherein the reactant comprises at least one of a halogen that halogenates the surface, a halogen combined with carbon (e.g., chlorofluorocarbons, CF₂Cl₂), a mixture of halogens (e.g., chlorine and fluorine), a sulphide so as to form the reactive layer comprising a sulphide, hydrogen or a hydride so as to form the reactive layer comprising a hydride, a nitride or nitrogen so as to form the reactive layer comprising a nitride, or oxygen or an oxide so as to form the reactive layer comprising an oxide.
13. The method of example 1, wherein the reactive layer comprises chlorinated silicon, the reactant comprises chlorine, bromine, or boron trichloride, and the agent comprises argon, neon, krypton, or helium ions.
14. The method of example 1, further comprising repeating steps (b) and (c) so as to perform a plurality of etching cycles each comprising the step (b) and the step (c), wherein:
the cycles include one or more first cycles and a second cycle subsequent to the first cycle,
the second cycle forms the reactive layer that is thinner as compared to the reactive layer formed in the first cycles, so that the processing in the second cycle processes the reactive layer with a finer resolution as compared to the etching in one or more the first cycles, and
the reactive layer in one or more of the first cycles is incrementally decreased in the (n+1)th first cycle as compared to the nth first cycle (the thickness of the reactive layer in one or more of the first cycles can be the same or gradually decreased).
15. The method of example 1 where the final cycle terminates without removal of the reactive layer.
16. The method of example 15 where the composition and/or thickness of the final reactive layer which remains is different than the reactive layer before it which was at least partially removed.
17. The method of example 16 where the composition and/or thickness of the final reactive layer is chosen to make the semiconductor substrate or layer be more amenable to subsequent processing.
18. The method of example 17 where the composition and/or thickness of the final reactive layer is chosen to enhance the electrical or optical properties of the final device.
19. The method of example 18 where the electrical property improved is carrier mobility or contact resistance.
20. The structure of example 15 where the final reactive layer acts as passivation to reduce or prevent change in air.
21. The structure of example 17 where the final reactive layer contains a halogen, nitrogen, carbon, sulphur, or hydrogen.
22. The structure of example 20 where the final reactive layer reduces or prevents oxidation of the semiconductor
23. The method of example 20 where the final reactive layer is made to be more amenable to removal in situ prior to a subsequent epitaxial growth step which results in a higher quality epitaxial growth than would have been achieved without the final reactive layer.
24. The structure of example 15 where the final reactive layer is incorporated into the final device.
25. The method of example 1, wherein the semiconductor comprises silicon or a compound that principally contains elements from group III and group V from the periodic table (a III-V material) or a compound that principally contains elements from group II and group VI of the periodic table (II-VI material), Si, Ge, or a superlattice of any of these materials.
26. The method of example 1, wherein the semiconductor comprises CdTe, CdZnTe. HgCdTe, InP, AlGaN, AlGaInP, GaN, GaSb, InAs, or GaAs.
27. The method of example 1 where the semiconductor is doped.
28. The method of example 27 where the dopants are Zn, Be, B, P, Sn, or Sb.
29. The method of example 1, wherein the dielectric layer comprises silicon dioxide, silicon nitride or lithium niobate.
30. An electronic (transistor) or optoelectronic device (e.g., LED, laser, photodetector (e.g., infrared photodetector, waveguide) grown on the smoothed or improved surface of example 1.
31. The method of example 1, wherein the semiconductor is grown by Metalorganic Chemical Vapor Deposition (MOCVD) or Molecular Beam Epitaxy (MBE).
32. The method of example 1, wherein the processing does not generate subsurface damage and does not increase dislocations at the surface as compared to in the bulk of the semiconductor.
33. The method of example 1, wherein the processing controls a dopant profile at the surface.
34. The method of example 1, further comprising repeating the steps (b) and (c) to remove residual protrusions.
35. An apparatus for etching a substrate, comprising:
one or more reactor tools reacting a reactant with a surface of a dielectric layer or semiconductor so as to form a reactive layer on the dielectric layer or the semiconductor, wherein the reactant comprises a gas or plasma, wherein the reactive layer comprises a chemical compound including the reactant and elements of the dielectric layer or the semiconductor; and
one or more tools outputting a treatment or processing agent for processing the reactive layers so as to at least smoothen, or control defects at, or otherwise treat the surface as described herein.
36. A wafer, comprising:
a processed surface of an epitaxial material comprising a semiconductor, wherein:
the processed surface comprises fewer defects as compared to the surface prior to processing compared to in a bulk of the substrate, and
the processed surface has a root mean square surface roughness of less than 1 nanometer over an entirety of the surface area of the wafer, and
the epitaxial layer is single crystalline
37. The wafer of example 36, wherein the defects are dislocations, pits, compositional irregularities, disordered regions, misordered regions, or scratches.
38. The method of example 1 where the smoothed and/or repairs take place in regions of a substrate and not in others.
39. The wafer of example 37 where the semiconductor material that is processed is only present only in some parts of the wafer

### BRIEF DESCRIPTION OF THE DRAWINGS

Referring now to the drawings in which like reference numbers represent corresponding parts throughout:

FIG. 1A. Etch Yield per Ion vs. Ion Energy.

FIG. 1B. Etch Yield per Ion vs. Angle of Incidence of Ion.

FIG. 2A-2D. Etch Protrusion Trimming, showing the etch rate is nearly the same in all directions, so that even though the substrate is also etched, the protrusions are trimmed in all directions and consequently shrink faster than the rate of etching of the flat surface FIG. 2C shows the protrusions trimmed or shrunk due to the etching as compared to in FIG. 2A and FIG. 2B). FIG. 2D illustrates etching of the reactive layer.

FIG. 3A. Atomic Force Microscope (AFM) of an InP mesa before the process is applied.

FIG. 3B. Scanning Electron Microscope (SEM) of the InP mesa semiconductor prior to processing.

FIG. 3C. Atomic Force Microscope (AFM) of the InP semiconductor of FIG. 3A after processing using the methods described herein. The surface is now ready for subsequent device processing or additional III-V epitaxial material growth.

FIG. 3D. Scanning Electron Microscope (SEM) of the semiconductor of FIG. 3A after the processing.

FIG. 4A-4D: AFM (height and phase channels pairs) of the surface of SiC prior to processing (4A-4B) illustrating an AFM line scan of a scratched epitaxial substrate surface before processing and the same substrate with fewer scratch defects after processing (4C-4D). The substrate is now ready for subsequent epitaxial material growth.

FIG. 5A-5B. Top view and cross sectional view of transistor with passivation according to embodiments described herein.

FIG. 6A-6F. SEM images showing Chlorine process without Fluorine results in InP “pillars” capped by SiO2

FIG. 7A. Flowchart illustrating a method of processing (e.g., etching) according to an embodiment.

FIG. 7B. Flowchart illustrating a method of processing according to an embodiment.

FIGS. 8A-8B. Example device structures planarized using the method.

FIG. 9. Example apparatus for etching, wherein FIG. 9A shows a tool wherein the reactive layer and processing are in the same chamber/tool, and FIG. 9B shows a tool wherein the reactive layer and processing are in the same chamber

FIG. 10. Computer for controlling various methods and apparatus described herein.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized, and structural changes may be made without departing from the scope of the present invention.

Technical Description

Nano-Planarization for Improved Fabrication and Performance of Semiconductor Devices

Atomic Layer Etching (ALE) is a method of precisely removing material from a substrate at a rate of no more than a few angstroms per second using a cyclical process. In plasma ALE, a reactive molecular gas is introduced into a vacuum chamber. A plasma is used to dissociate that gas into its atomic constituents and other activated species such as radicals, ions, and metastable excited species. Conventional plasma etching uses a biased electrode to accelerate those ions towards a substrate of interest. The ions collide with the surface and stimulate chemical reactions to occur, some of which lead to the formation of volatile products. For example, chlorine and argon gas can be combined in a plasma to form Cl atoms, Ar ions, etc. to etch silicon.

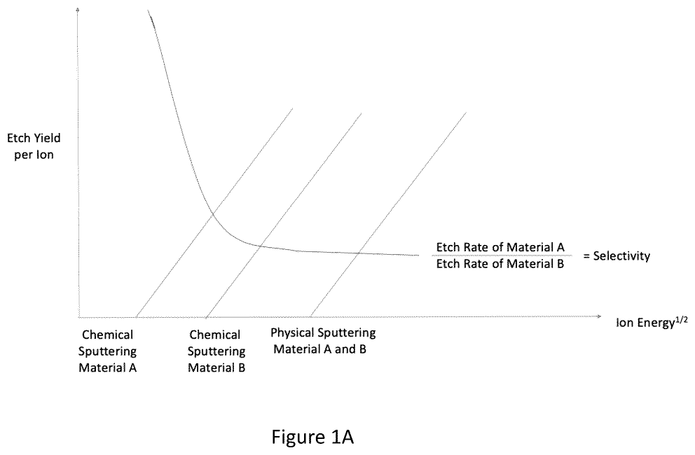

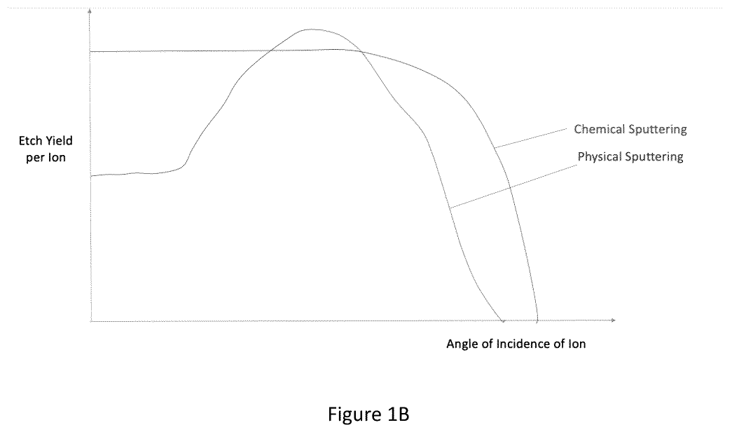

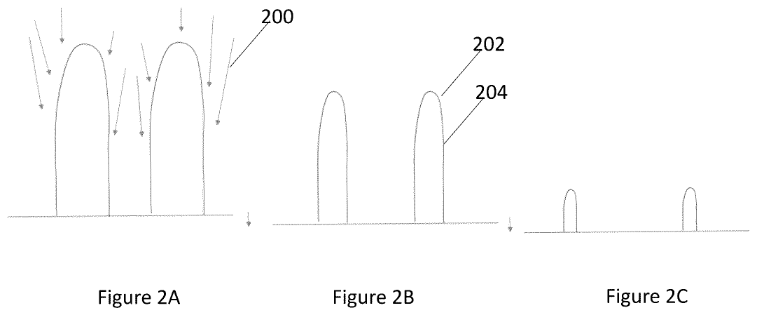

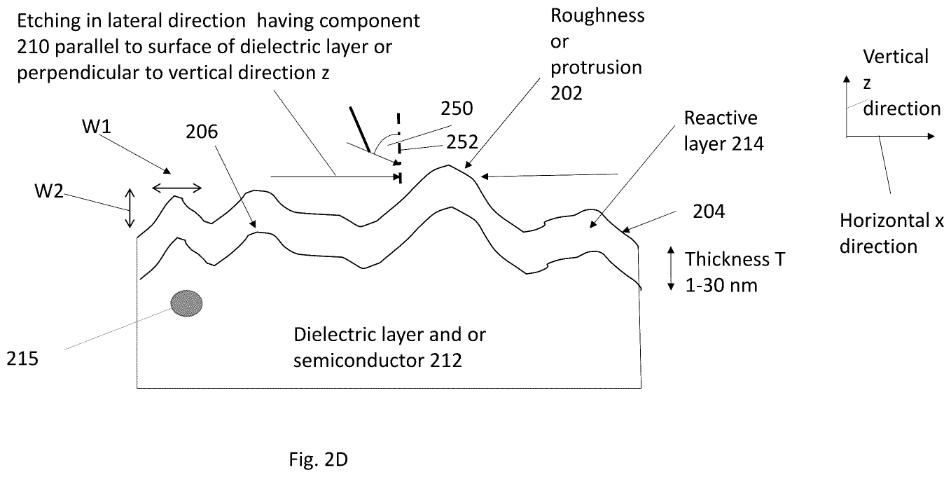

FIGS. 1-2D illustrate a unique method of processing a surface using atomic layer etching, wherein the ion 200 energy, ion angular distribution, and chemistry can be precisely controlled to planarize a surface with nanometer resolution. By minimizing the ion energy, increasing the ion angular distribution (through low bias, high pressure, and chemistry) the lateral etch rate of features, protrusions 202, and roughness on the surface can be significantly increased.

### First Example: Atomic Layer Etching

An example ALE process on a silicon substrate comprises the following separate discrete steps:
1. A very low power chlorine and argon plasma is used to dissociate molecular chlorine gas into chlorine atoms. Those atoms absorb to the silicon surface forming an ultrathin film of chlorinated silicon. The chlorination process stops when the layer fully covers the exposed surface
2. The chlorine gas flow is turned off, leaving a pure argon plasma behind. The residual chlorine is removed from the gas phase by being pumped out. However, the chlorinated layer on the silicon remains behind.
3. Once the chlorine is gone from the gas phase completely (purged from the chamber), a very small electrical bias is applied to the pedestal upon which the wafer is sitting. That causes argon ions to be gently accelerated towards the wafer. The energy of the ions impacting the wafer is just high enough to impart energy to the atoms in the chlorinated silicon layer. Silicon bonds to silicon break and subsequently reform by connecting silicon directly to chlorine, leading to the production of volatile species such as SiCl₄. Eventually, all of the chlorine in the chlorinated surface layer formed in step 1 is consumed to produce SiCl₄, and the reactions stop. The remaining silicon is not etched because the ion energy from the plasma bias is not sufficient to sputter silicon atoms away. Thus, this etching step is saturating because the thickness of the chlorinated layer is defined and controlled by step 1.
4. The bias is removed and the ion bombardment stops. The SiCl₄ reaction products are pumped away and the plasma chamber and wafer surface have been renewed.

The process repeats cycling from steps 1 to 4 until the desired amount of material is precisely removed.

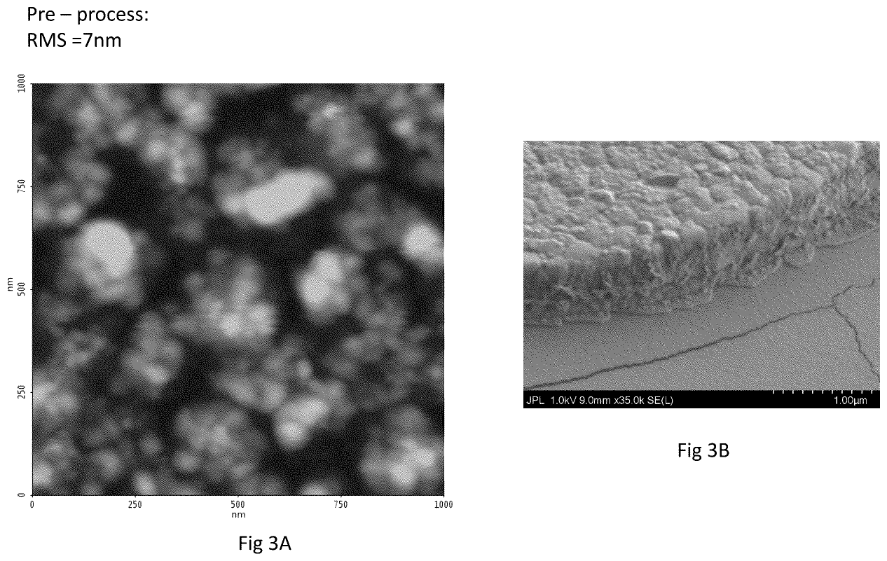

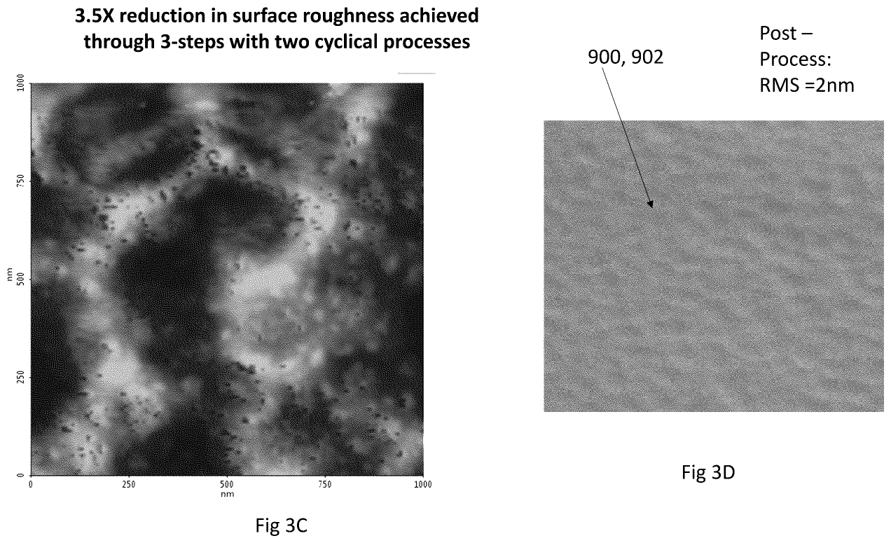

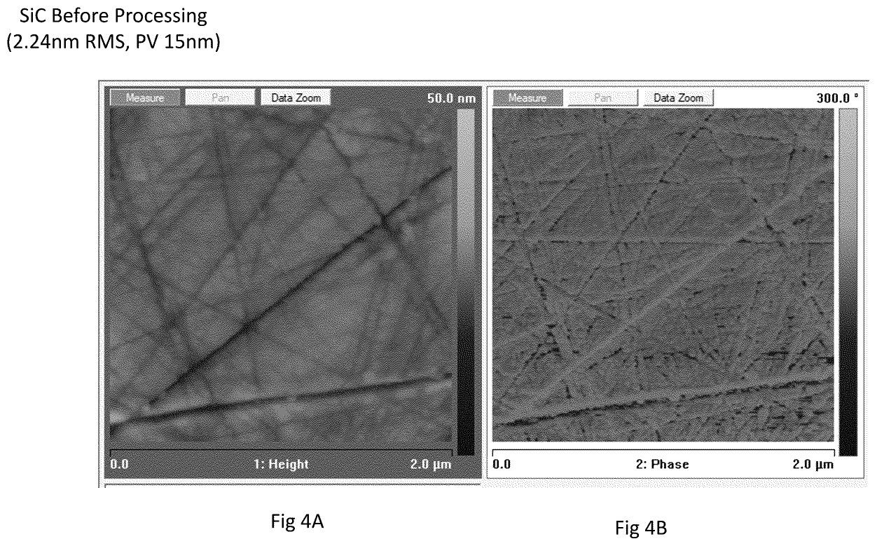

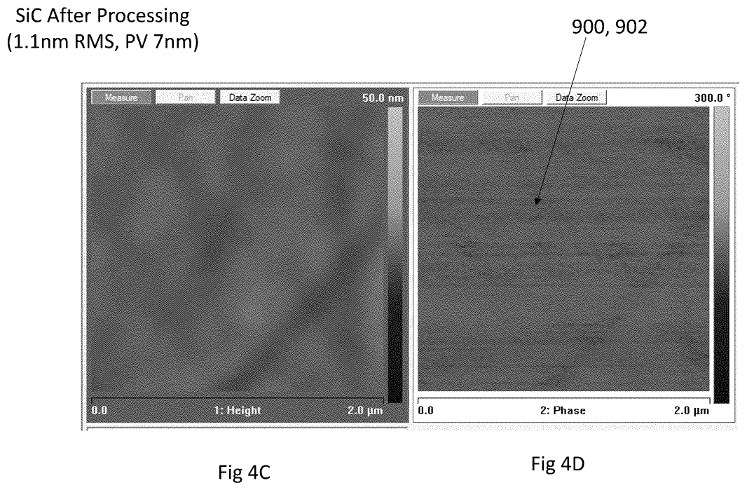

FIGS. 3A-3D and 4A-4D shows how an ALE process dramatically reduces the submicron scale roughness in a manner that is not achievable by any other etching or polishing process. This nano-planarization approach with ALE can controllably remove the large protrusions in the dielectric layer (caused by underlying wiring) in a quasi-conformal fashion, because the sidewalls of the protrusions have a portion of their projected area that is exposed to the argon ions from the plasma. In addition, since the bias voltage in step 3 is low, the ion transit time through the plasma sheath to the wafer is relatively long (as compared to conventional etching). The longer ion transit time results in a broader ion angular distribution impacting the wafer, including the ions having trajectories incident on the substrate at angles up to nearly 10 degrees off normal, as compared to incident angles 1-2 degrees off normal that are achieved using higher biases during conventional etching. The broader ion angular distribution leads to a substantially greater lateral etch rate so that the protrusions are etched from all sides. Ultimately, the protrusions can be eliminated or nearly eliminated, leaving a flat surface upon which subsequent processes can be performed.

Epitaxial Substrate Smoothing

Removing submicron scale roughness or protrusions can be used for nanoplanarization of epitaxial surfaces. In growth of materials by MOCVD or MBE, it is usually desirable to maintain the epitaxial character of the substrate so as to obtain the best electronic properties of the newly grown materials. However, in order to achieve this, the growth surface must be contamination-free and as smooth as possible to avoid defects. In certain applications, it is not possible to use chemical-mechanical polishing of the substrate to smooth the material (especially when it is grown in small regions on a non-epitaxial substrate). It is, therefore, useful to remove submicron roughness from these MOCVD or MBE template regions using atomic layer etch. To remove the contamination, atomic layer etching can be used. For example, an InP epitaxial template grown using a SiO₂ capping layer may have residues of SiO₂ left behind, or native oxides of the InP, even after an HF strip of the material. ALE chemistries involving fluorine can be used to remove the SiO₂ or other oxides. A chlorine-based chemistry can then be used to smooth the InP surface, remove defects, and/or passivate the surface to make it more amenable to subsequent epitaxial growth techniques. These two processes working together yield an extremely smooth surface upon which to grow high quality materials such as InGaAs for shortwave infrared detector applications. The surface of the smoothed semiconductor, such as GaN, InAs, etc. can be subsequently coated with a dielectric material to form a MOSFET (Metal Oxide Semiconductor Field Effect Transistor), a HEMT (High Electron Mobility Transistor), or other electronic device structure. This smooth surface interface between the processed surface and the subsequent dielectric results in superior device properties, such as channel mobility, gate leakage, etc. The surfaces of epitaxial growth substrates and wafers such as SiC, GaN, GaAs, CdZnTe can also be improved in this manner,

Controlling Dopant and/or Defect Profiles

In addition to smoothing, the techniques described herein can be used to control or remove/etch/protect defects, scratches, bumps, pits (V-pits), dislocations (e.g., threading dislocations), or dopant profiles.

For example, in may be desirable to enrich or deplete the dopant, by leveraging the fact that some dopants are more or less volatile that the surrounding material in the semiconductor (thereby increasing or suppressing removal of the dopant as compared to surrounding materials). For example, the processing can sharpen dopant profile, increase doping at the surface, or create a dopant profile wherein dopants concentration is increased and then decreased moving from the surface to the bulk (low-high-low). In one or more examples, the dopant profile is tailored for formation of contacts (e.g., ohmic contacts). In one example Boron trichlorode is used for etching a semiconductor doped with Zinc). This modulation of dopant volatility compared to the other constituents of the semiconductor substrate or layer can be modified by choosing a reactive species that leads to a reactive layer with semiconductor compounds that are more or less amenable for removal than the dopant in the reactive layer removal step. A dopant species like Zn which has a volatile chloride, for example, would be selectively removed as compared to the Indium in InP since InCl3 is much less volatile than ZnCl2.

In yet further examples, the processing may be tailored (e.g., smoothened) to render the surface more amenable for doping.

Controlling Surface Properties (e.g., Passivation)

Channels in typical HEMT devices must be passivated for chemical stability to reduced undesirable scattering of charge carriers. For example, III-V oxides can be particularly detrimental for scattering. Typical solutions include forming a PECVD coating formed on the surface of the channel.

FIG. 3 illustrates an example transistor device, comprising source, drain, channel, gate dielectric, and gate, wherein the surface of the channel has been smoothened and/or passivated using the methods described herein. For example, the reactive layer formed on the surface of the semiconductor in the channel region can passivate and/or cap the semiconductor, e.g., to form non-oxygen or non-oxide bonds with the semiconductor that prevent oxidation or other unwanted environmental degradation of the semiconductor. The gate dielectric and gate can then be deposited on the reactive layer.

In some examples, multiple reactive layer formation steps can be formed. For example, one or more cycles may comprise forming a reactive layer and removing the reactive layer to smoothen and/or control doping, and/or repair defects, and then a final reactive layer formation step (wherein the reactive layer is not removed) to form the capping/passivation.

Moreover, the final passivation reactive layer can be precisely tailored to optimize its passivation properties. For example, the processing agent (ion bombardment) can be used to treat the reactive layer to make it more amenable for subsequent processing or device performance and/or as a passivation layer. In one or more examples, the ion bombardment densifies and/or rearranges the reactive layer to make it more amenable.

Controlling Isotropy/Anisotropy and Controlling Composition of the Reactive Layer

The isotropy of the processing can be controlled to control removal or treatment of the surface by selection or control of at least one of the reactant composition, treatment or processing temperature, or angle of incidence of the processing agent (e.g., ions) on the surface.

In one or more embodiments, the reaction between the semiconductor and the reactant (or processing agent used to treat the reactive layer during the processing step) is a thermally activated/induced reaction so that the rate of the reaction of the reactant/processing agent with the semiconductor increases exponentially with increasing temperature according to the Arrhenius equation

$$k = A e \frac{- {E}_{a}}{RT}$$

k=rate constant
Eₐ=activation energy (in the same units as R*T)
T=absolute temperature (in: Kelvin)

The rates of reaction of the reactant/processing agent with constituent elements in compound semiconductors (e.g., In, P, Ga, N, and As in InP, InAs, and GaN) can be independently controlled. The processing conditions and chemistries can be tailored to leverage the different volatility of the constituent elements, or the different vapor pressures of the compounds formed with reactant and the constituent elements, to control isotropy of the processing (e.g., etching). Temperature can also be used to control the composition of the reactive layer and effectiveness of the removal process. At lower temperatures, compounds such as InCl3 will be less volatile than PCl3, so one can control the relative removal rates of In and P compounds during the removal step. This can be taken all the way to the extreme where nearly all P is removed from the surface, and the final layer will be only InCl3. At the other extreme, the temperature can be optimized such that the removal rates of In and P compounds are sufficiently similar that no enrichment occurs.

(i) Reactant Chemistry/Composition (e.g., Halogen Choice)

Reactivity of the reactant (e.g., halogen) with the semiconductor, and vapor pressure of the compound formed between the reactant and the semiconductor can be selected to increase anisotropy of the processing (e.g., etching) by selecting the appropriate agent to tune the chemistry of the reactive layer or by manipulating the processing agent in the removal step (e.g. change the angular distribution or energy of the ions). Typically constituent elements with higher volatility, or compounds with higher vapor pressure in the presence of the processing agent (e.g., free chlorine or free fluorine) lead to more isotropic (increased lateral/sidewall etching). Typically, the reactivity of halogens with semiconductors such as silicon is such that F>Br>Cl (i.e., Fluorine is more reactive than Bromine which is more reactive than chlorine), so that the halogen (e.g., fluorine) can be selected to create compounds with the semiconductor that have higher vapor pressure (which correlates with more sidewall/lateral etch). The reactivity of halogens with semiconductors that fall into the category of III-V materials often have the reverse reactivity where Cl>Br>Fl.

(ii) Temperature of the Processing

The reaction of the constituent elements of the semiconductor with the reactant/processing agent is a thermally activated/induced reaction so that the rate of the reaction is according to the Arrhenius equation (i.e., the rate increases exponentially as the temperature increases). The temperature of the reaction can be cooled/reduced so that the reaction of the reactive layer with the processing agent is negligible and the processing is more anisotropic, or the processing temperature can be heated up to render the processing more isotropic.

Moreover, the temperature can be selected to balance reaction rates that control etching or processing of the constituent elements of the semiconductor.

In one example processing (e.g., etching) InAs with a halogen, it is noted that AsCl and InCl have different k's and activation energies in the Arrhenius equation (e.g., arsenic chloride is more volatile than indium chloride). While at room temperature AsCl₃ is initially formed in higher quantities (and therefore etched at a higher rate) than InCl₃, as the temperature is increased to 100 degrees Celsius or more, the InCl₃ formation (and resulting etch rate of InCl3) increases faster than the rate of AsCl₃). Thus, at lower temperatures, processing (e.g., etching) in the presence of the processing agent (reactant) is more anisotropic, or the temperature can be selected/increased for equal/matching etch rates of the constituent elements (equal etch rate of In and As in InAs), taking into account that the Group V element is typically more volatile than the Group III element.

The temperature can be further controlled to balance volatility and/or prevent formation of a surface with undesirable enrichment of one constituent element over another (i.e., prevent formation of so called enrichment bumps).

(iii) Angle of Incidence of the Processing Agent (e.g., Ions) on the Surface.

The angle of incidence of the ions can be controlled to determine the isotropy or anisotropy, e.g., so that the ratio of the vertical processing rate (etch rate) and the horizontal processing (etch rate) can be modified. In one or more examples, the isotropy/anisotropy is controlled by accelerating ions onto the surface so that a majority of the ions impact the surface at an angle of at least 10 degrees with respect to a surface normal, at an angle of 30-40 degrees with respect to the surface normal, or perpendicular to the surface. In typical examples, the angle is controlled by bias voltage accelerating the ions and/or pressure of the atmosphere containing the ions. The ions can either comprise reactive ions (e.g., chlorine, fluorine, bromine) comprising the reactant used to form the reactive layer, or inert ions which may be used in the removal step.

In yet further examples, it is noted that the processing of the reactive layer comprises (1) a physical “billiard ball” component that is a function of incidence of the processing (e.g., ions) and (2) a chemical reaction component (chemical reaction of the ions with the reactive layer that is stimulated by the ion bombardment) that is a function of both temperature and the angle of incidence of the ions. As described herein, one or more of the angle of incidence, temperature, and reactant composition can be tailored to selectively control relative vaporization of each of chemical constituents of the semiconductor (in their compound form with the reactant, e.g., InCl₃, AsCl₃) from the semiconductor, so as to control relative removal/processing/etching of the constituents of the semiconductor, and therefore the anisotropy or isotropy of the processing.

One or more of, or a combination of, the above described techniques can be used to control or remove/etch at least one of roughness, scratches, defects, bumps, pits (V-pits), dislocations (e.g., threading dislocations), elemental enrichment in the surface as compared to the bulk material, or doping profiles, or otherwise treat (e.g., passivate) or repair the surface. For example, at least one of the isotropy/anisotropy, temperature, reactant composition, angle of incidence can be tuned to decrease or increase the etch rate of defects (temperature, gas composition, ion bombardment). In typical examples, removal of scratches requires etch faster in the horizontal direction (e.g., along the scratch) than in the vertical direction to make the scratches less deep and more broad as the processing takes place until the desired final morphology is reached.

Example Process Steps

FIG. 3 is a flowchart illustrating a method of smoothing or improving a substrate (referring also to FIGS. 1-5C).

Block 700 represents obtaining a substrate comprising a semiconductor with optionally a dielectric layer 212 on or above the semiconductor.

Block 702 represents reacting a surface of the dielectric layer or semiconductor (e.g., group III-V semiconductor or other semiconductor) with a reactant, comprising a gas or a plasma, to form a reactive layer. The reactive layer comprises a chemical compound including the reactant and elements of the dielectric layer or the semiconductor. The reactive layer further comprises the protrusions 202 having sidewalls 204 (see FIG. 2).

In one example, the reactant comprises a halogen (e.g., chlorine, fluorine, bromine) that halogenates the surface. In other examples, the reactant comprises a sulphide so as to form the reactive layer comprising a sulphide, or hydrogen or a hydride so as to form the reactive layer comprising a hydride or reduced surface, or nitrogen or a nitride so as to form the reactive layer comprising a nitride. In another example, the reactant comprises an oxidizer that oxidizes the surface to form the reactive layer comprising an oxide. Example oxidation processes include, but are not limited to, subjecting the substrate to a high temperature in oxygen (although some metals may flow and agglomerate), subjecting the substrate to UV ozone exposure at room temperature, subjecting the substrate to oxygen radicals from a downstream plasma, or oxidation with a direct plasma with O₂ gas-based mixtures.

In other examples, the reactant comprises a reactive ion that reacts with a semiconductor to form the reactive layer.

Block 704 represents etching the reactive layer and the protrusions laterally through the sidewalls so as to planarize the surface and remove or shrink the protrusions.

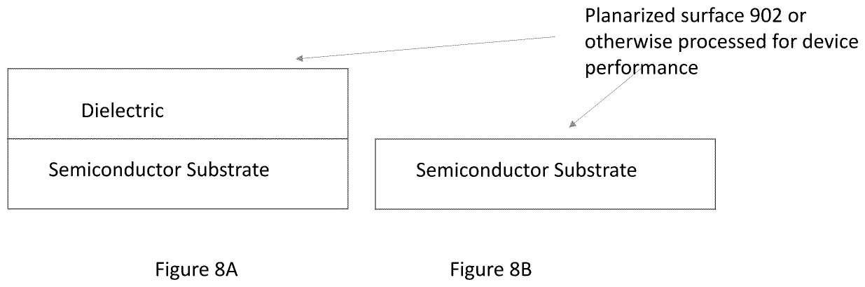

Block 706 represents the end result, a planarized substrate or wafer for subsequent deposition of device layers (also illustrated in FIGS. 8, 4).

FIG. 8A-8B illustrates an example wherein the wafer comprises a wafer or a substrate for a device, comprising an etched surface of an epitaxial layer comprising a semiconductor, wherein:
the etched surface “as etched” without further processing or treatment:
   does not comprise an increased number of dislocations as compared to in a bulk of the substrate, and
   has a root mean square surface (RMS) roughness of less than 1 nanometer over an entirety of a surface area of the wafer, and
the epitaxial layer is single crystalline and does not comprise disordered amorphous layer.

In on or more examples, the RMS surface roughness is in a range of 0.1-1 nm or 0.2-1 nm over the surface of the area of a 2, 3, 4, 6, 8, or 12 inch diameter wafer.

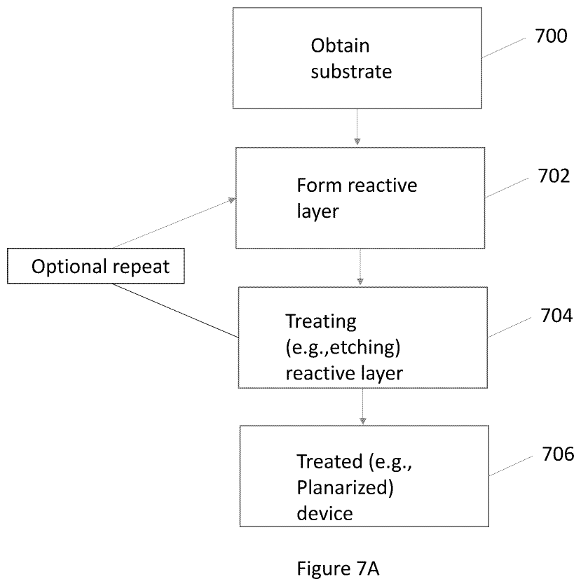

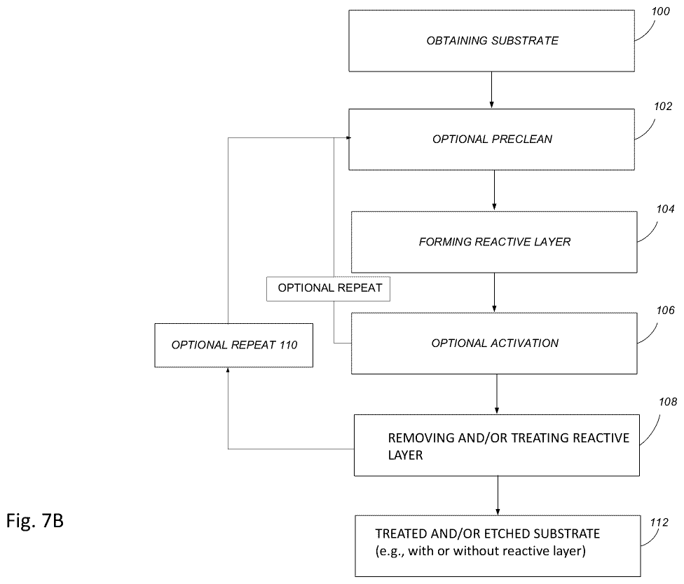

FIG. 7B illustrates a method for treating/etching (e.g., atomic layer etching ALE) a surface according to one or more examples. The method comprises the following steps.

Block 100 represents obtaining a substrate comprising a material. Example materials include, but are not limited to, a semiconductor (e.g., silicon, a III-V material, or a II-VI material).

Block 102 represents optionally pre-cleaning a surface of the substrate (e.g., using argon ion bombardment, oxygen cleaning, thermal treatment, UV treatment, or hydrogen reduction).

Block 104 represents reacting a surface (e.g., the pre-cleaned surface) of a substrate with a reactant, comprising a gas or a plasma, to form a reactive layer or skin on the substrate, the reactive layer or skin comprising a chemical compound including the reactant and the material. In one example, the reactant comprises a halogen (e.g., chlorine, fluorine, bromine) that halogenates the surface. In other examples, the reactant comprises a sulphide so as to form the reactive layer comprising a sulphide, or hydrogen or a hydride so as to form the reactive layer comprising a hydride or reduced surface, or nitrogen or a nitride so as to form the reactive layer comprising a nitride. In another example, the reactant comprises an oxidizer that oxidizes the surface to form the reactive layer comprising an oxide. Example oxidation processes include, but are not limited to, subjecting the substrate to a high temperature in oxygen, subjecting the substrate to UV ozone exposure at room temperature, subjecting the substrate to oxygen radicals from a downstream plasma, or oxidation with a direct plasma with O₂ gas-based mixtures.

Block 106 represents optionally performing an activation step (activating the reactive layer e.g., using argon ion bombardment). Note that it is possible to return to Block 102 and complete several cycles through blocks 102-106 prior to moving on to Block 108 (the etching or removal of the reactive layer).

Block 108 represents etching/treating the reactive layer (e.g., the activated reactive layer), e.g., using a self-limiting or atomic layer etch or treatment. In one example, treatment represents one or more exposures of the reactive layer to a fluid or a liquid. That liquid or series of liquids can etch away or dissolve or treat or rearrange or densify the reactive layer. In one example, etching or treating comprises dry etching the wet etched surface, e.g., using ions in a plasma. In one or more examples, the ion energy, ion angular distribution, and chemistry can be precisely controlled in a cyclic fashion. For example, minimizing the ion energy, increasing the ion angular distribution (through low bias, high pressure, and chemistry), one can ensure that the lateral etch rate of features is maximized. In one or more examples, the ions are accelerated using a relatively low bias voltage and such that the ion transit time through the plasma sheath to the substrate is relatively long, resulting in a broader ion angular distribution impacting the wafer (nearly 10 degrees off normal, as compared to 1-2 degrees for high bias conventional etching). Under such conditions, the protrusions are etched from all sides due to a substantially greater lateral etch rate. Ultimately, the protrusions can be eliminated or nearly eliminated, leaving a flat surface upon which to do subsequent processes, or to achieve a smoother substrate for an additional purpose.

An atomic layer or self-limiting etch is not unique to plasma-based processes. Any process where a self-limiting reaction layer can be formed and then later removed in an etching step can be utilized to reduce the roughness of materials. In one or more further examples, wet or thermal processes can be used to create and remove the reactive layer, and various processing techniques can be combined to achieve a desired result. Thus, in one or more examples, the step comprises etching the reactive layer with a (e.g., liquid) wet etchant that selectively etches the reactive layer but not the substrate (or selectively etches the reactive layer much more effectively or at a much larger etching rate as compared to the substrate). In various examples, the reaction layer is transformed into a liquid/fluid phase by the etchant. In various examples, the wet etching comprises an isotropic wet etch.

In yet another example, the reactive layer is etched or removed or treated using a thermal process or an ion bombardment.

In one or more examples, the etching or removal in step 108 includes a combination of any two processes selected from a dry etch, ion bombardment, a wet etch, and a thermal process (which can optionally be combined into one ALE sequence).

Block 110 represents optionally repeating at least steps 104 and 108 (or the sequence of steps 102-108) so as to perform a plurality of etching or treatment cycles. In one or more examples, the etching or treatment cycles include a first cycle and a second cycle subsequent to the first cycle, wherein the second cycle optionally forms the reactive layer that is thinner as compared to the reactive layer formed in the first cycle, so that the wet etching in the second cycle (or dry etching in second cycle) etches the reactive layer with a finer resolution as compared to the wet etching in the first cycle. Further cycles can also be tailored to form thinner and thinner reaction layers. In one or more examples, the final step can leave the cycle with the reactive layer intact.

Block 112 represents the end result, an etched or treated substrate, e.g., as illustrated in FIG. 8.

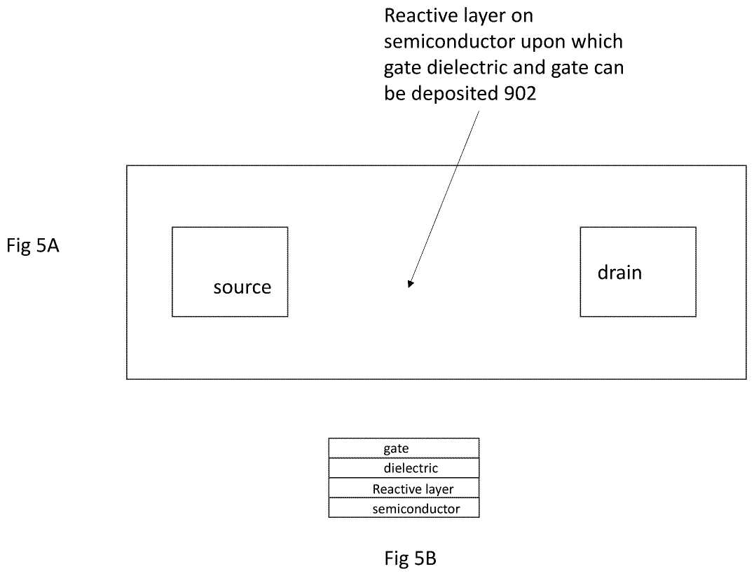

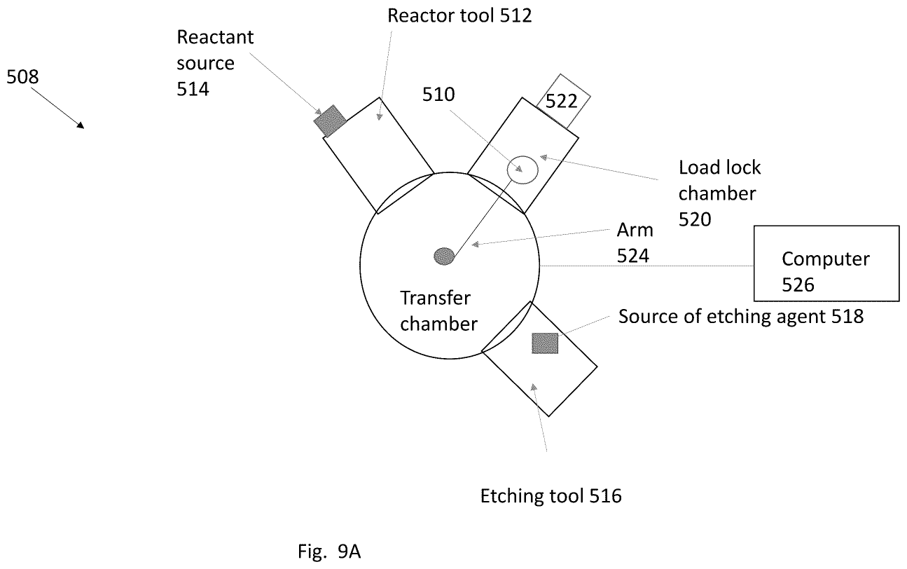

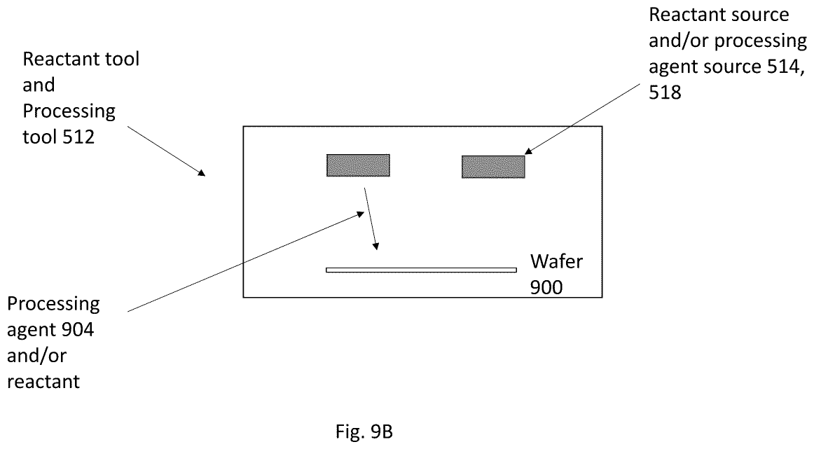

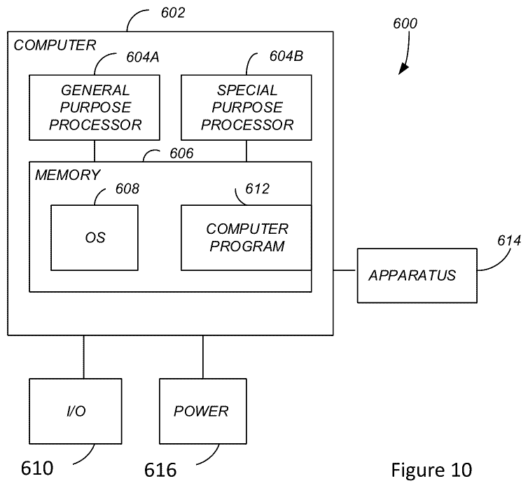

Illustrative embodiments of the subject matter described herein include, but are not limited to the following examples (referring also to FIGS. 1-10).
1. A method for processing a surface, comprising:
(a) obtaining a substrate 900 comprising an epitaxially grown semiconductor 212 or an ordered substrate template for subsequent epitaxial growth of a semiconductor;
(b) reacting a surface 206 of the semiconductor and/or a surface of a dielectric layer on the semiconductor, with a reactant comprising a gas, a plasma, or a fluid, to form a reactive layer 214 on the dielectric layer and/or the semiconductor, wherein the reactive layer comprises a chemical compound including the reactant and elements of the dielectric layer or the semiconductor; and
(c) processing (e.g., removing, modifying, and/or chemically reducing) the reactive layer, e.g., with an agent 904 wherein the processing at least smoothens, or controls defects at, or processes or treats the surface 206.
2. The method of example 1, wherein the processing comprises reacting the reactive layer with an agent 904 that induces a re-arrangement of chemical bonds between constituents of the reactive layer and wherein the re-arrangement removes at least part of the constituents of the reactive layer from the surface.
3. The method of example 2, wherein the reacting comprises projecting the agent onto the surface with an energy:
   below that required for physical sputtering of the surface using the agent so that the material is not ejected from the substrate by a physical sputtering process, and
   sufficient to act as a catalyst for the re-arrangement.
4. The method of example 2 or 3, wherein the agent comprises ions.
5. The method of any of the examples 1-4, wherein the processing comprises accelerating ions onto the surface and selecting an angle 250 of incidence of the ions with respect to a surface normal 252 so as to smoothen or remove the defects from the surface.
6. The method of any of the examples 1-5, wherein the processing comprises accelerating ions onto the surface and at least one of:
selecting a temperature of the processing,
selecting an angle of incidence of the processing,
selecting a composition of the reactant, or
selecting an angle of incidence of the ions onto the surface, and
so as to control anisotropy or isotropy of removal of the reactive layer.
7. The method of example 6, wherein the processing comprises removing and/or treating the reactive layer along a direction having a larger component 210 parallel to the surface of the reactive layer, as compared to the component normal to the surface.
8. The method of any of the examples 1-7, wherein the formation of the reactive layer comprises and at least one of:
selecting a temperature of the processing, or
selecting a composition of the reactant,
so as to control anisotropy or isotropy of formation of the reactive layer.
9. The method of any of the examples 1-8, wherein the processing comprises chemical sputtering.
10. The method of any of the examples 1-9, wherein the processing comprises wet etching with a liquid wet etchant.
11. The method of any of the examples 1-10, wherein the reactive layer comprises protrusions 202 and valleys having sidewalls and the processing etches the valleys laterally through the sidewalls so as to planarize the surface and remove or connect the valleys.
12. The method of example 11, wherein the valleys have a height W2 and width W1 in a range of 1-1000 nm.
13. The method of any of the examples 1-12, wherein the reactant comprises at least one of a halogen that halogenates the surface, a halogen combined with carbon (e.g., chlorofluorocarbons, CF₂Cl₂), a mixture of halogens (e.g., chlorine and fluorine), a sulphide so as to form the reactive layer comprising a sulphide, hydrogen or a hydride so as to form the reactive layer comprising a hydride, a nitride or nitrogen so as to form the reactive layer comprising a nitride, or oxygen or an oxide so as to form the reactive layer comprising an oxide.
14. The method of any of the examples 1-12, wherein the reactive layer comprises chlorinated silicon, the reactant comprises chlorine, bromine, or boron trichloride, and the agent comprises argon, neon, krypton, or helium ions.
15. The method of any of the examples 1-14, further comprising repeating steps (b) and (c) so as to perform a plurality of etching cycles each comprising the step (b) and the step (c), wherein:
the cycles include one or more first cycles and a second cycle subsequent to the first cycle,
the second cycle forms the reactive layer that is thinner as compared to the reactive layer formed in the first cycles, so that the processing in the second cycle processes the reactive layer with a finer resolution as compared to the etching in one or more the first cycles, and
the reactive layer in one or more of the first cycles is incrementally decreased in the (n+1)th first cycle as compared to the nth first cycle (the thickness of the reactive layer in one or more of the first cycles can be the same or gradually decreased).
16. The method of any of the examples 1-15, wherein the final cycle terminates without removal of the reactive layer.
17. The method of example 15 or 16 wherein the composition and/or thickness of the final reactive layer which remains is different than the reactive layer before it which was at least partially removed.
18. The method of any of the examples 15-17 where the composition and/or thickness of the final reactive layer is chosen to make the semiconductor substrate or layer be more amenable to subsequent processing.
19. The method of any of the examples 15-18 where the composition and/or thickness of the final reactive layer is chosen to enhance the electrical or optical properties of the final device.
20. The method of any of the examples 15-19 where the electrical property improved is carrier mobility or contact resistance.
21. A structure formed using the method of any of the examples 1-20 where the final reactive layer acts as passivation to reduce or prevent change in air.
22. A structure formed using the method of any of the examples 1-21 where the final reactive layer contains a halogen, nitrogen, carbon, sulphur, or hydrogen.
22. A structure formed using the method of any of the examples 1-22 where the final reactive layer reduces or prevents oxidation of the semiconductor
23. The method of any of the examples 1-22 where the final reactive layer is made to be more amenable to removal in situ prior to a subsequent epitaxial growth step which results in a higher quality epitaxial growth than would have been achieved without the final reactive layer.
24. The structure of any of the examples 1-23 where the final reactive layer is incorporated into the final device.
25. The method of any of the examples, wherein the semiconductor comprises silicon or a compound that principally contains elements from group III and group V from the periodic table (a III-V material) or a compound that principally contains elements from group II and group VI of the periodic table (II-VI material), Si, Ge, or a superlattice of any of these materials.
26. The method of any of the examples 1-25, wherein the semiconductor comprises CdTe, CdZnTe. HgCdTe, InP, AlGaN, AlGalnP, GaN, GaSb, InAs, or GaAs.
29. The method of any of the examples 1-26 where the semiconductor is doped.
30. The method of example 29 where the dopants 215 are Zn, Be, B, P, Sn, or Sb.
31. The method of any of the examples 1-30, wherein the dielectric layer comprises silicon dioxide, silicon nitride or lithium niobate.
32. An electronic (transistor) or optoelectronic device (e.g., LED, laser, photodetector (e.g., infrared photodetector, waveguide) grown on the smoothed or improved surface of any of the examples 1-31.
33. The method of any of the examples 1-32, wherein the semiconductor is grown by Metalorganic Chemical Vapor Deposition (MOCVD) or Molecular Beam Epitaxy (MBE).
34. The method of any of the examples 1-33, wherein the processing does not generate subsurface damage and does not increase dislocations at the surface as compared to in the bulk of the semiconductor.
35. The method of any of the examples 1-34, wherein the processing controls a dopant profile at the surface.
36. The method of any of the examples 1-35, further comprising repeating the steps (b) and (c) to remove residual protrusions 202.
37. An apparatus 500 for etching a substrate, comprising:
one or more reactor tools 512 reacting a reactant with a surface of a dielectric layer or semiconductor so as to form a reactive layer on the dielectric layer or the semiconductor, wherein the reactant comprises a gas or plasma, wherein the reactive layer comprises a chemical compound including the reactant and elements of the dielectric layer or the semiconductor; and
one or more tools 514 outputting a treatment or processing agent 904 for processing the reactive layers so as to at least smoothen, or dope, or control defects at, or passivate, o otherwise treat (as described herein) the surface of the semiconductor or the reactive layer.
38. A wafer 900, comprising:
a processed surface 902 of an epitaxial material layer comprising a semiconductor 212, wherein:
the processed surface comprises fewer defects as compared to the surface prior to processing compared to in a bulk of the substrate, and
the processed surface has a root mean square surface roughness of less than 1 nanometer over an entirety of the surface area of the wafer, and
the epitaxial material layer is single crystalline
39. The wafer of example 38, wherein the defects are dislocations, pits, compositional irregularities, disordered regions, misordered regions, or scratches.
40. The method of any of the examples, where the smoothed and/or repairs take place in regions of a substrate and not in others.
41. The wafer of example 38 or 39 where the semiconductor material that is processed is only present only in some parts of the wafer
42. The wafer, method, or apparatus of any of the examples 1-41, wherein the processing agent used to treat the active layer comprises a gas (e.g., noble gas) or ions e.g., comprising one or more of argon, neon, helium, nitrogen or krypton.
43. The wafer, method, or apparatus of any of the examples 1-42, further comprising leaving the reactive layer as a capping layer on the semiconductor and optionally treating or processing the reactive layer, so that the reactive layer provides or can be used to manipulate desirable device properties for the device or subsequent device layers deposited on the reactive layer (e.g., advantageous contact resistance or manipulated transistor properties, electrical or optical behaviour).
44. The wafer, method, or apparatus of any of the examples 1-43, wherein the processing of the reactive layer controls a composition of the reactive layer and/or renders the reactive layer more amenable of subsequent repair/fixing of dislocations/defects and/or controlling final composition of the reactive layer.
45. The wafer, method, or apparatus of any of the examples 1-44, noting that the component constituents of the semiconductor (group III, Group V, Group II, Group VI elements) are etched or respond to processing differently, and tailoring the angle of incidence, temperature, and/or reactant composition to tailor relative etch rate or response of the component constituents.
46. The wafer, method, or apparatus, of any of the examples 1-45, further comprising treating the reactive layer to make it more amenable for removal/subsequent processing or device performance, wherein the treatment comprises ion bombardment to densify or rearrange the reactive layer.
47. The wafer, method, apparatus of any of the examples 1-46, wherein the reactive layer comprises a combination (e.g., mixture, compound of) the reactant and constituents of the semiconductor, and the processing of the reactive layer causes each of the constituents of the semiconductor bonded to the reactant to be vaporized or otherwise removed from the reactive layer.
48. The wafer, method, or apparatus of any of the examples 1-47, further comprising controlling composition of the reactive layer and/or conditions of the treatment of the reactive layer to control isotropy (vertical and/or horizontal direction processing) of the treatment of the reactive layer to control composition, defects repair, smoothing, doping, etc. as described herein.
49. The apparatus of example 37 performing the method of any of the examples 1-48. FIG. 5 illustrates an example apparatus for etching a substrate, comprising one or more reactor tools reacting a reactant with a surface of a dielectric layer or semiconductor so as to form a reactive layer on the dielectric layer or the semiconductor, wherein the reactant comprises a gas or plasma, wherein the reactive layer comprises a chemical compound including the reactant and elements of the dielectric layer or the semiconductor. The apparatus further includes one or more etching tools selectively etching protrusions in the dielectric layer or the semiconductor, laterally through sidewalls of the protrusions, so as to planarize the surface and remove or shrink the protrusions or otherwise perform the treatments of the reactive layer and/or semiconductor described herein.
50. The wafer of any of the examples 38-39 fabricated using the method or apparatus of any of the examples 1-49.
51. A device manufactured using the method, wafer, or apparatus of any of the examples 1-50.
52. The device or wafer of example 51, comprising a single processed layer (reactive layer) that enhances smoothness, passivation, reduced defects, and/or doping as described herein.
53. The device or wafer of example 52 without a separate PECVD or ammonium sulphide layer.
54. The device, wafer, method or apparatus of any of the examples 1-53 utilizing the tools or methods in references [1]-[3].
55. The device, wafer, method or apparatus of any of the examples 1-54, wherein a thickness T of the reactive layer on sidewalls of the protrusions is controlled to be greater or smaller than the thickness in regions between the protrusions 202.
56. The device, wafer, method or apparatus of any of the examples wherein the processing does at least one of: smoothening, doping control, defect control, or passivation, or reactive layer formation, or one or more of the treatments described herein.

Advantages and Improvements

The underlying physics of the process described here process has profound implications for topology control. First, and most importantly, chemically enhanced sputtering (as is described in step 3 above) is fundamentally different than pure physical sputtering. Since the etching process in chemically enhanced sputtering operates through deposition of energy to achieve chemical rearrangement (rather than ejection of atoms through elastic recoil as in physical sputtering), the angular dependence of the etching yield of an incoming ion is fundamentally different. Purely physical sputtering processes have a substantial peak in their etching yield at around 45 degrees of ion incidence, leading to faceting where etching along certain angles is preferred, and potentially resulting in undesirable surface morphologies. Chemical sputtering, on the other hand, is largely independent of ion angle and therefore enables all surfaces of a peak on a surface to be etched at roughly the same etch rate.

Example Computer Hardware

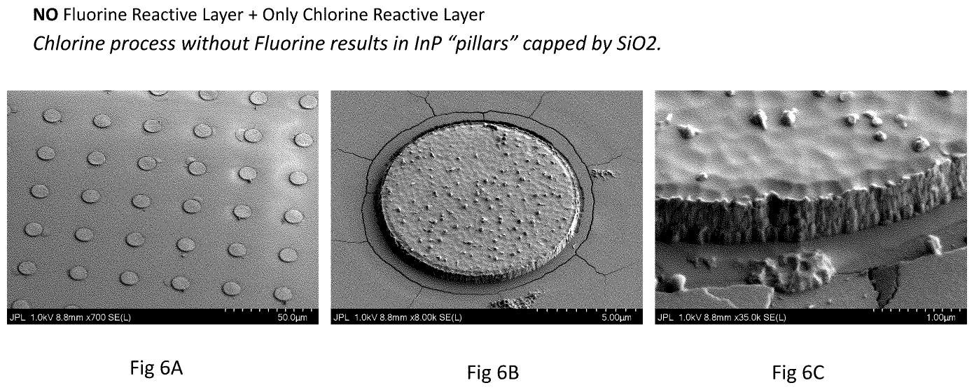

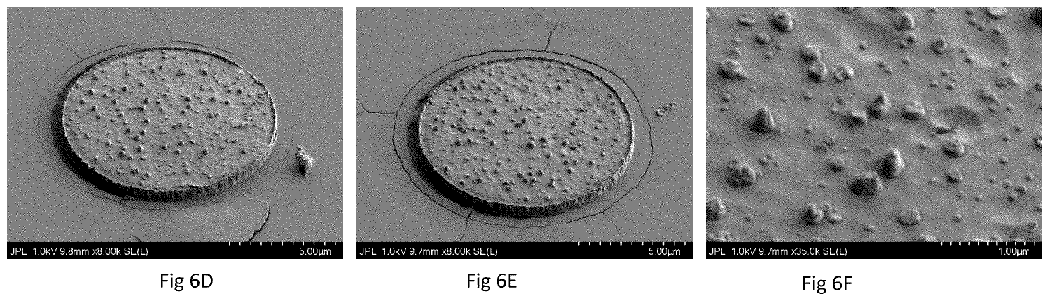

FIG. 6 illustrates an exemplary system 600 that could be used to implement processing elements needed to control the etching apparatus 508 (e.g., 614) described herein.

The computer 602 comprises a processor 604 (general purpose processor 604A and special purpose processor 604B) and a memory, such as random access memory (RAM) 606. Generally, the computer 602 operates under control of an operating system 608 stored in the memory 606, and interfaces with the user/other computers to accept inputs and commands (e.g., analog or digital signals) and to present results through an input/output (I/O) module 610. The computer program application 612 accesses and manipulates data stored in the memory 606 of the computer 602. The operating system 608 and the computer program 612 are comprised of instructions which, when read and executed by the computer 602, cause the computer 602 to perform the operations herein described. In one embodiment, instructions implementing the operating system 608 and the computer program 610 are tangibly embodied in the memory 606, thereby making a computer program product or article of manufacture. As such, the terms “article of manufacture,” “program storage device” and “computer program product” as used herein are intended to encompass a computer program accessible from any computer readable device or media.

In one embodiment, computer 602 comprises one or more field programmable gate arrays (FPGAs) or application specific integrated circuits (ASIC).

The computer can comprise one or more processors, one or more memories, wherein an application or program stored in the memories and executed on the processors can perform the methods described herein.

### REFERENCES

The following references are incorporated by reference herein
[1] US Patent Publication No. 2021-0313185
[2] US 2022-0013706
[3] Atomic Layer-Based Surface Treatments for Infrared Detectors Publication number: 20230129191.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method for processing a surface, comprising:
(a) obtaining a substrate comprising an epitaxially grown semiconductor or an ordered substrate template for subsequent epitaxial growth of a semiconductor;
(b) reacting a surface of the semiconductor and/or a surface of a dielectric layer on the semiconductor, with a reactant comprising a gas, a plasma, or a fluid, to form a reactive layer on the dielectric layer and/or the semiconductor, wherein the reactive layer comprises a chemical compound including the reactant and elements of the dielectric layer or the semiconductor; and
(c) processing (e.g., removing and/or chemically reducing) the reactive layer, wherein the processing at least smoothens, or controls defects at, the surface.

2. The method of claim 1, wherein the processing comprises reacting the reactive layer with an agent that induces a re-arrangement of chemical bonds between constituents of the reactive layer and wherein the re-arrangement removes at least part of the constituents of the reactive layer from the surface.

3. The method of claim 2, wherein the reacting comprises projecting the agent onto the surface with an energy:
below that required for physical sputtering of the surface using the agent so that the material is not ejected from the substrate by a physical sputtering process, and
sufficient to act as a catalyst for the re-arrangement.

4. The method of claim 2, wherein the agent comprises ions.

5. The method of claim 1, wherein the processing comprises accelerating ions onto the surface and selecting an angle of incidence of the ions with respect to a surface normal so as to smoothen or remove the defects from the surface.

6. The method of claim 1, wherein the processing comprises accelerating ions onto the surface and at least one of:
selecting a temperature of the processing,
selecting an angle of incidence of the processing,
selecting a composition of the reactant, or
selecting an angle of incidence of the ions onto the surface, and
so as to control anisotropy or isotropy of removal of the reactive layer.

7. The method of claim 6, wherein the processing comprises removing the reactive layer along a direction having a larger component parallel to the surface of the reactive layer, as compared to the component normal to the surface.

8. The method of claim 1, wherein the formation of the reactive layer comprises and at least one of:
selecting a temperature of the processing, or
selecting a composition of the reactant,
so as to control anisotropy or isotropy of formation of the reactive layer.

9. The method of claim 1, wherein the processing comprises chemical sputtering or wet etching with a liquid wet etchant.

10. The method of claim 1, wherein the reactive layer comprises valleys having sidewalls and the processing etches the valleys laterally through the sidewalls so as to planarize the surface and remove or connect the valleys.

11. The method of claim 9, wherein the valleys have a height and width in a range of 1-1000 nm.

12. The method of claim 1, wherein the reactant comprises at least one of a halogen that halogenates the surface, a halogen combined with carbon, a mixture of halogens, a sulphide so as to form the reactive layer comprising a sulphide, hydrogen or a hydride so as to form the reactive layer comprising a hydride, a nitride or nitrogen so as to form the reactive layer comprising a nitride, or oxygen or an oxide so as to form the reactive layer comprising an oxide.

13. The method of claim 1, wherein the reactive layer comprises chlorinated silicon, the reactant comprises chlorine, bromine, or boron trichloride, and the agent comprises argon, neon, krypton, or helium ions.

14. The method of claim 1, further comprising repeating steps (b) and (c) so as to perform a plurality of etching cycles each comprising the step (b) and the step (c), wherein:
the cycles include one or more first cycles and a second cycle subsequent to the first cycle,
the second cycle forms the reactive layer that is thinner as compared to the reactive layer formed in the first cycles, so that the processing in the second cycle processes the reactive layer with a finer resolution as compared to the etching in one or more the first cycles, and
the reactive layer in one or more of the first cycles is incrementally decreased in the (n+1)th first cycle as compared to the nth first cycle (the thickness of the reactive layer in one or more of the first cycles can be the same or gradually decreased).

15. The method of claim 14 where the final cycle terminates without removal of the reactive layer.

16. The method of claim 15 wherein:
the composition and/or thickness of the final reactive layer which remains is different than the reactive layer before it which was at least partially removed, and/or
the composition and/or thickness of the final reactive layer is chosen to make the semiconductor substrate or layer be more amenable to subsequent processing, and/or
the composition and/or thickness of the final reactive layer is chosen to enhance the electrical or optical properties of the final device.

17. The method of claim 16 where the electrical property improved is at least one of carrier mobility or contact resistance.

18. The method of claim 15, comprising forming a structure wherein:
the final reactive layer acts as passivation to reduce or prevent change in air, and/or
the final reactive layer comprises a halogen, nitrogen, carbon, sulphur, or hydrogen, and/or
the final reactive layer reduces or prevents oxidation of the semiconductor, and/or
the final reactive layer is incorporated into the final device, and/or
the final reactive layer is made to be more amenable to removal in situ prior to a subsequent epitaxial growth step which results in a higher quality epitaxial growth than would have been achieved without the final reactive layer.

19. The method of claim 1, wherein the semiconductor comprises:
silicon or a compound that principally contains elements from group III and group V from the periodic table (a III-V material) or a compound that principally contains elements from group II and group VI of the periodic table (II-VI material), Si, Ge, or a superlattice of any of these materials, and/or
the semiconductor is doped.

20. The method of claim 1, wherein the processing controls a dopant profile at the surface.

21. An apparatus for etching a substrate, comprising:
one or more reactor tools reacting a reactant with a surface of a dielectric layer or semiconductor so as to form a reactive layer on the dielectric layer or the semiconductor, wherein the reactant comprises a gas or plasma, wherein the reactive layer comprises a chemical compound including the reactant and elements of the dielectric layer or the semiconductor; and
one or more tools outputting a treatment or processing agent for processing the reactive layers so as to at least smoothen, or control defects at, the surface.

22. A wafer, comprising:
a processed surface of an epitaxial material comprising a semiconductor, wherein:
the processed surface comprises fewer defects as compared to the surface prior to processing compared to in a bulk of the substrate, and
the processed surface has a root mean square surface roughness of less than 1 nanometer over an entirety of the surface area of the wafer, and
the epitaxial layer is single crystalline, and wherein the defects are dislocations, pits, compositional irregularities, disordered regions, misordered regions, or scratches.
